(19) United States
(12) Patent Application Publication
(10) Pub. No.: US 2025/0226349 A1
(43) Pub. Date: Jul. 10, 2025

(54) SEMICONDUCTOR PACKAGE AND METHOD OF MANUFACTURING THE SAME

(71) Applicant: Samsung Electronics Co., Ltd., Suwon-si (KR)

(72) Inventors: Minseok Jang, Suwon-si (KR); Jaehyeon Lim, Suwon-si (KR)

(21) Appl. No.: 18/987,530

(22) Filed: Dec. 19, 2024

(30) Foreign Application Priority Data
Jan. 8, 2024 (KR) 10-2024-0002807
Feb. 16, 2024 (KR) 10-2024-0022234

(51) Int. Cl. H01L 23/00; H01L 23/498; H01L 25/18

(52) U.S. Cl. CPC H01L 24/32; H01L 24/30; H01L 25/18; H01L 23/49838; H01L 2224/221; H01L 2224/24265; H01L 2224/26175; H01L 2224/32111

(57) ABSTRACT

A semiconductor package includes a first redistribution layer (RDL) including a first redistribution wiring structure, an insulation layer contacting a lower surface of the first RDL, the insulation layer including an opening exposing a lower surface of a portion of the first redistribution wiring structure, a pad in the opening, the pad contacting the lower surface of the portion of the first redistribution wiring structure and including solder, a second semiconductor chip contacting a lower surface of the pad, and an underfill member in the opening. The underfill member does not contact a lower surface of a portion of a lower surface of the insulation layer adjacent to the opening, and the underfill member at least partially at least partially overlaps sidewalls of the pad and the second semiconductor chip in the first direction.

### CROSS-REFERENCE TO RELATED APPLICATIONS

This application claims priority under 35 U.S.C. § 119 to Korean Patent Application Nos. 10-2024-0002807 and 10-2024-0022234, filed on Jan. 8, 2024 and Feb. 16, 2024,respectively, in the Korean Intellectual Property Office (KIPO), the contents of which are herein incorporated by reference in their entirety.

### TECHNICAL FIELD

Example embodiments relate to a semiconductor package and a method of manufacturing the same.

### BACKGROUND

In a method of manufacturing a fan out wafer level package (FOWLP), an insulation layer is formed on a redistribution layer (RDL), the insulation layer is partially removed to form an opening, a copper pad is formed in the opening to contact an upper surface of the insulation layer, solder paste is coated on the copper pad, a chip is mounted on the solder paste, and a reflow process and an underfill process are performed.

An underfill member formed by the underfill process may contact and cover a surface of a solder ball, so that an electrical connection between the solder ball and a conductive element contacting the solder ball may be poor.

### SUMMARY

Example embodiments provide a semiconductor package having enhanced electrical characteristics.

Example embodiments provide a method of manufacturing a semiconductor package having enhanced electrical characteristics.

According to example embodiments, there is provided a semiconductor package. The semiconductor package may include a first redistribution layer (RDL) including a first redistribution wiring structure, a package substrate on an upper surface of the first RDL, a first semiconductor chip on the first RDL, the first semiconductor chip spaced apart from the package substrate in a first direction that is parallel to the upper surface of the first RDL, an insulation layer contacting a lower surface of the first RDL, the insulation layer including an opening exposing a lower surface of a portion of the first redistribution wiring structure, a pad in the opening, the pad contacting the lower surface of the portion of the first redistribution wiring structure and including solder, a second semiconductor chip contacting a lower surface of the pad, the second semiconductor chip including a passive element, and an underfill member in the opening, the underfill member not contacting a lower surface of a portion of a lower surface of the insulation layer adjacent to the opening, and the underfill member at least partially at least partially overlapping sidewalls of the pad and the second semiconductor chip in the first direction.

According to example embodiments, there is provided a semiconductor package. The semiconductor package may include a redistribution layer (RDL) including a redistribution wiring structure, a package substrate on an upper surface of the RDL, a first semiconductor chip on the RDL, the first semiconductor chip spaced apart from the package substrate in a first direction that is parallel to the upper surface of the RDL, an insulation layer contacting a lower surface of the RDL, the insulation layer including an opening exposing a lower surface of a portion of the redistribution wiring structure, a pad in the opening, the pad contacting the lower surface of the portion of the redistribution wiring structure and including solder, and an upper surface of the pad is substantially coplanar with the lower surface of the RDL, a second semiconductor chip contacting a lower surface of the pad, the second semiconductor chip including a passive element, and a protective layer at least partially at least partially overlapping sidewalls of the pad and the second semiconductor chip in a second direction that is perpendicular to the upper surface of the RDL, the protective layer including epoxy.

According to example embodiments, there is provided a method of manufacturing a semiconductor package. In the method, a package substrate and a first semiconductor chip may be mounted on a first surface of a redistribution layer (RDL) including the first surface and a second surface opposite to the first surface in a vertical direction, and a redistribution wiring structure. An insulation layer may be formed on the second surface of the RDL. The insulation layer may be partially removed to form a first opening exposing a portion of the redistribution wiring structure. A complex adhesion layer may be formed on the exposed portion of the redistribution wiring structure. The complex adhesion layer may include solder and epoxy. A second semiconductor chip may be mounted on the complex adhesion layer, and may include a passive element. A reflow process may be performed on the complex adhesion layer to form a first pad and a protective layer. The first pad may contact an upper surface of the exposed portion of the redistribution wiring structure and a lower surface of the second semiconductor chip, and may include solder. The protective layer may at least partially cover sidewalls of the first pad and the second semiconductor chip, and may include epoxy.

According to example embodiments, a semiconductor package includes a redistribution layer (RDL) including a redistribution wiring structure, a package substrate on an upper surface of the RDL, a first semiconductor chip on the RDL, the first semiconductor chip spaced apart from the package substrate in a first direction that is parallel to the upper surface of the RDL, an insulation layer contacting a lower surface of the RDL, the insulation layer including a first opening and a second opening that expose a first portion of the redistribution wiring structure and a second portion of the redistribution wiring structure, respectively, a first pad in the first opening and contacting the first portion of the redistribution wiring structure, a second pad in the second opening and contacting the second portion of the redistribution wiring structure, a conductive connection member contacting a lower surface of the first pad, a second semiconductor chip contacting a lower surface of the second pad, and an underfill member in the second opening. The lower surface of the second pad and the lower surface of the RDL are separated by a first distance in a second direction that is perpendicular to the upper surface of the RDL, a lower surface of the insulation layer and the lower surface of the RDL are separated by a second distance in the second direction, and the underfill member does not contact a portion of a lower surface of the insulation layer between the first opening and the second opening.

In the method of manufacturing the semiconductor package in accordance with example embodiments, the underfill member covering or overlapping the chip including the electrode and the pad contacting the pad may be formed to not contact the conductive bump without forming a dam structure. Thus, the process for forming the dam structure may be skipped and the space for the dam structure may be saved. As a result, the integration degree of the semiconductor package may be enhanced.

### BRIEF DESCRIPTION OF THE DRAWINGS

FIG. 1 is a cross-sectional view illustrating a semiconductor package in accordance with example embodiments.

FIGS. 2 to 13 are plan views and cross-sectional views illustrating a method of manufacturing a semiconductor package in accordance with example embodiments.

### DETAILED DESCRIPTION OF EXAMPLE EMBODIMENTS

Hereinafter, example embodiments will be explained in detail with reference to the accompanying drawings. It will be understood that, although the terms “first,” “second,” and/or “third” may be used herein to describe various materials, layers (films), regions, electrodes, pads, patterns, structures and processes, these materials, layers (films), regions, electrodes, pads, patterns, structures and processes should not be limited by these terms. These terms are only used to distinguish one material, layer (film), region, electrode, pad, pattern, structure and process from another material, layer (film), region, electrode, pad, pattern, structure and process. Thus, a first material, layer (film), region, electrode, pad, pattern, structure and process discussed below could be termed a second or third material, layer (film), region, electrode, pad, pattern, structure and process without departing from the teachings of inventive concepts.

Two crossing directions among horizontal directions that are substantially parallel to an upper surface of a panel or a package substrate may be referred to as first and second directions D1 and D2, respectively, and a vertical direction that is substantially perpendicular to the upper surface of the panel or the package substrate may be referred to a third direction D3. In example embodiments, the first and second directions D1 and D2 may be substantially perpendicular to each other.

To clarify the present disclosure, the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection. The term “exposed” may be used to define a relationship between particular layers or surfaces, but it does not require the layer or surface to be free of other elements or layers thereon in the completed device. Components or layers described with reference to “overlap” in a particular direction may be at least partially obstructed by one another when viewed along a line extending in the particular direction or in a plane perpendicular to the particular direction.

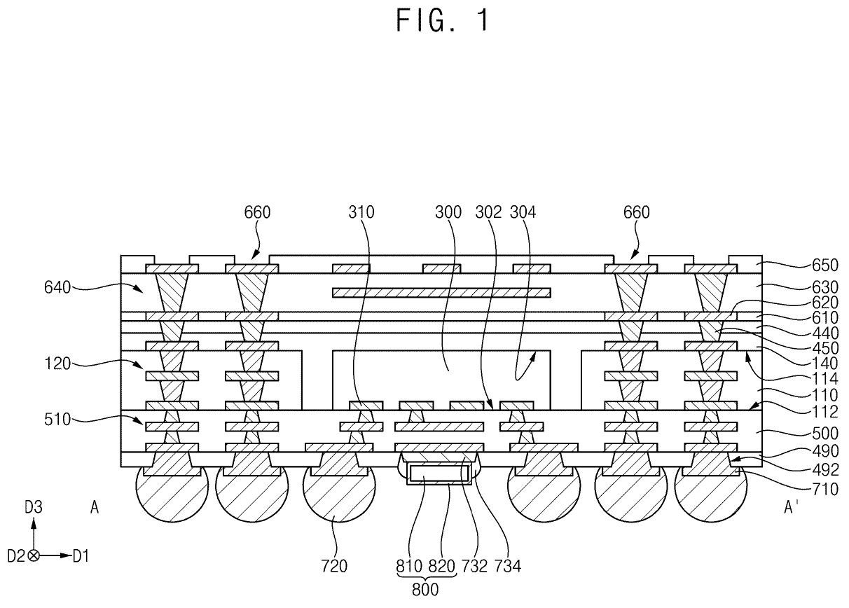

FIG. 1 is a cross-sectional view illustrating a semiconductor package in accordance with example embodiments.

Referring to FIG. 1, the semiconductor package may include a first redistribution layer (RDL) 500, a package substrate 110 and a first semiconductor chip 300 spaced apart from each other in the horizontal direction on the first RDL 500, a molding layer 140 on the first RDL 500 and covering or overlapping a space in the first direction D1 between the package substrate 110 and the first semiconductor chip 300 and upper surfaces of the package substrate 110 and the first semiconductor chip 300, a first adhesion layer 440, a second insulation layer 610, a second RDL 630 and a first protective layer 650 sequentially stacked on the molding layer 140 in the third direction D3, a second adhesion layer 490, fourth and fifth pads 710 and 732, a conductive connection member 720, an underfill member 734 and a second semiconductor chip 800 under or on a lower surface of the first RDL 500.

The semiconductor package may further include a conductive via 450 and a second pad 620.

The first RDL 500 may include first insulating interlayers stacked in the third direction D3 and a first redistribution wiring structure 510 in the first insulating interlayers. The first redistribution wiring structure 510 may include, e.g., first pads, contact plugs, vias and wirings, etc., and FIG. 1 shows some of the elements of the first redistribution wiring structure 510.

Each of the first insulating interlayers may include an organic material such as photo imageable dielectric (PID). Each of the first pads, contact plugs, vias and wirings may include a conductive material, e.g., a metal, a metal nitride, a metal silicide, etc.

The package substrate 110 may include first and second surfaces 112 and 114 opposite to each other in the third direction D3, and the first surface 112 of the package substrate 110 may contact an upper surface 504 of the first RDL 500. The package substrate 110 may include a semiconductor material, e.g., silicon, germanium, silicon-germanium, etc., glass or an organic material.

A wiring structure 120 may be disposed in the package substrate 110, and may contact the first redistribution wiring structure 510 in the first RDL 500 to be electrically connected thereto. In example embodiments, the wiring structure 120 may include, e.g., substrate pads, contact plugs, vias, wirings, etc., and some of the elements of the wiring structure 120 are shown in FIG. 1. Each of the substrate pads, the contact plugs, the vias, the wirings, etc., may include a conductive material, e.g., a metal, a metal nitride, a metal silicide, etc.

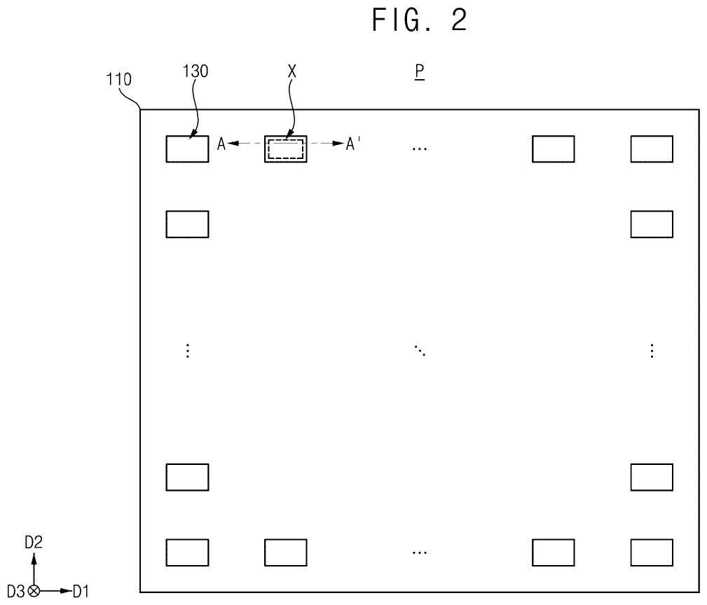

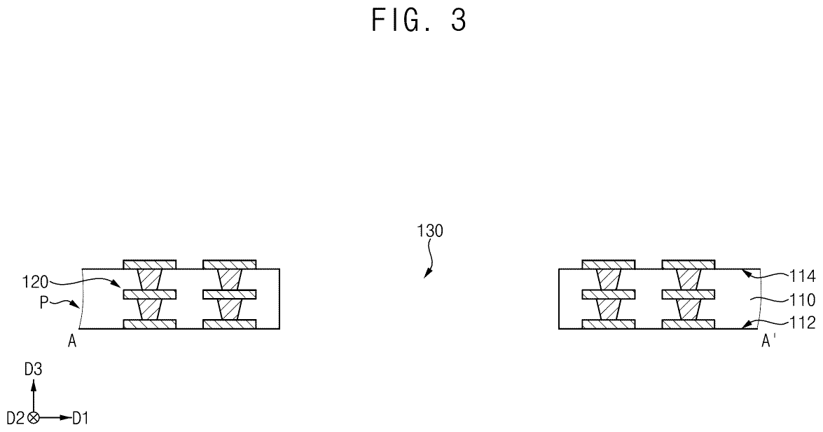

Referring to FIG. 1 together with FIGS. 2 and 3, the first semiconductor chip 300 may be disposed in a first opening 130 in the package substrate 110. The first semiconductor chip 300 may include first and second surfaces 302 and 304 opposite to each other in the third direction D3, and the first surface 302 of the first semiconductor chip 300 may contact an upper surface 504 of the first RDL 500 exposed by the first opening 130. Chip pads 310 may be disposed in the first semiconductor chip 300, and may contact the first redistribution wiring structure 510 in the first RDL 500 to be electrically connected thereto.

The first semiconductor chip 300 may include, e.g., a memory device, a logic device, etc., and thus may also be referred to as a memory chip, a logic chip, etc., or a memory die, a logic die, etc.

The molding layer 140 may be disposed on the first RDL 500, may at least partially fill the first opening 130 in the package substrate 110, and may contact the second surface 114 of the package substrate 110 and the second surface 304 of the first semiconductor chip 300. The molding layer 140 may include an organic material, e.g., epoxy, polymer, etc.

The first adhesion layer 440 may include an organic material, e.g., epoxy, polymer, etc. In an example embodiment, the first adhesion layer 440 may include Ajinomoto build-up film (ABF) having a multi-layered structure having a polybuthylene terephthalate (PET) film, a thermosetting resin and a protective film sequentially stacked.

The conductive via 450 may extend through the first adhesion layer 440 and an upper portion of the molding layer 140, and may contact a portion of the wiring structure 120 in the package substrate 110, e.g., the substrate pads. The conductive via 450 may include a metal, e.g., copper, aluminum, etc.

The second insulation layer 610 may include an organic material, e.g., epoxy, polymer, etc. In an example embodiment, the second insulation layer 610 may include ABF.

The second pad 620 may extend through the second insulation layer 610, and may contact an upper surface of the conductive via 450.

The second RDL 630 may include second insulating interlayers stacked in the third direction D3 and a second redistribution wiring structure 640 in the second insulating interlayers. The second redistribution wiring structure 640 may include, e.g., third pads, contact plugs, vias and wirings, etc., and FIG. 1 shows some of the elements of the second redistribution wiring structure 640. In example embodiments, the second redistribution wiring structure 640 may contact the second pad 620 and electrically connected thereto.

Each of the second insulating interlayers may include an organic material such as PID. Each of the third pads, contact plugs, vias and wirings may include a conductive material, e.g., a metal, a metal nitride, a metal silicide, etc.

The first protective layer 650 may be disposed on the second RDL 630, and may cover or overlap some of the third pads included in the second redistribution wiring structure 640 in the third direction D3. However, a fourth opening 660 exposing upper surfaces of some of the third pads may be formed in the first protective layer 650. The first protective layer 650 may include, e.g., solder resist (SR).

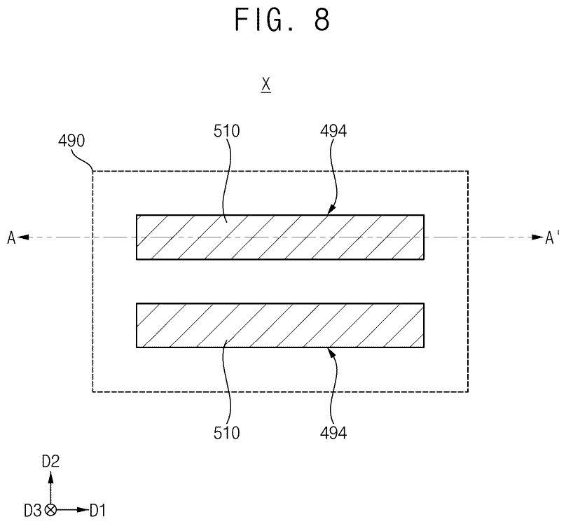

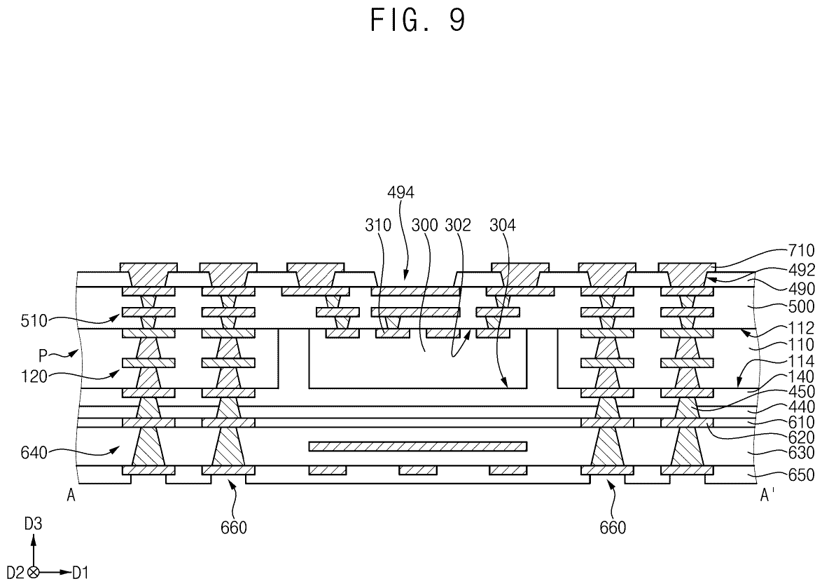

Referring to FIG. 1 together with FIGS. 8 and 9, the second adhesion layer 490 may contact a lower surface 502 of the first RDL 500, and fifth and sixth openings 492 and 494 may be formed through the second adhesion layer 490 to expose lower surfaces of the first pads included in the first redistribution wiring structure 510. A plurality of fifth openings 492 may be spaced apart from each other in each of the first and second directions D1 and D2. The sixth opening 494 may extend in the first direction D1, and a plurality of sixth openings 494, e.g., two sixth openings 494 may be spaced apart from each other in the second direction D2.

In example embodiments, each of the fifth and sixth openings 492, 494 may have a width in the first direction DI that gradually decreases from a bottom toward a top thereof in the third direction D3, that is, as each of the fifth and sixth openings 492, 494 gets closer to the lower surface 502 of the first RDL 500. Thus, a sidewall of the second adhesion layer 490 in each of the fifth and sixth openings 492, 494 may not be perpendicular to the first surface 112 of the package substrate 110 but slanted or sloped.

The second adhesion layer 490 may include an organic material, e.g., epoxy, polymer, etc. In an example embodiment, the second adhesion layer 490 may include ABF. In some case, the second adhesion layer 490 may also be referred to as a first insulation layer.

The fourth pad 710 may at least partially fill the fifth opening 492 in the second adhesion layer 490, and may contact lower surfaces of the first pads included in the first redistribution wiring structure 510. Additionally, the fourth pad 710 may include a protrusion portion that may protrude or extend from the fifth opening 492 downwardly in the third direction D3, and may contact a lower surface of the second adhesion layer 490. The fourth pad 710 may include a metal, e.g., copper, nickel, gold, etc.

The fifth pad 732 may be disposed in the sixth opening 494 in the second adhesion layer 490, and may contact lower surfaces of the first pads included in the first redistribution wiring structure 510. In example embodiments, the fifth pad 732 may extend in the first direction D1, and thus a length in the first direction D1 of the fifth pad 732 may be greater than a length in the second direction D2 of the fifth pad 732.

In example embodiments, a lower surface of the fifth pad 732, which faces the second semiconductor chip 800, may be higher than or substantially coplanar with a bottom of the sixth opening 494, which is opposite to the top end of the opening that exposes the first redistribution wiring structure 510. For example, the lower surface of the fifth pad 732 and the lower surface 502 of the first RDL 500 are separated by a first distance in the third direction D3, the bottom of the sixth opening 494 and the lower surface 502 of the first RDL 500 are separated by a second distance in the third direction D3, and the first distance is less than or equal to the second distance. In some embodiments, an upper surface of the second adhesion layer 490 including the sixth opening 494 and an upper surface of the fifth pad 732 may be substantially coplanar with a lower surface 502 of the first RDL 500. In example embodiments, the fifth pad 732 may have a width in the first direction D1 that gradually increases from a bottom toward a top thereof in the third direction D3, that is, as the fifth pad 732 gets closer to the lower surface 502 of the first RDL 500.

The fifth pad 732 may include, e.g., solder.

The conductive connection member 720 may contact a lower surface of the fourth pad 710. In an example embodiment, the conductive connection member 720 may cover or overlap not only a lower surface of the protrusion portion of the fourth pad 710 in the third direction D3 but also a sidewall thereof in the first direction D1. The conductive connection member 720 may be, e.g., a ball or a bump including, e.g., solder.

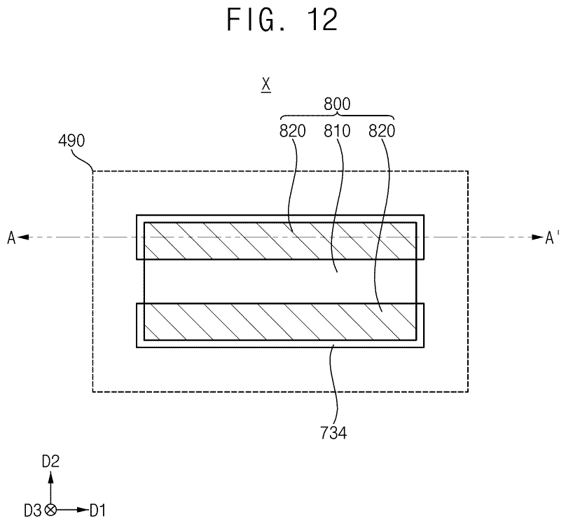

Referring to FIG. 1 together with FIG. 12, the second semiconductor chip 800 may contact a lower surface of the fifth pad 732, and may include a body 810 and electrodes 820 covering or at least partially overlapping surfaces of opposite edge portions of the body 810. Each of the electrodes 820 may extend in the first direction D1, and may cover or at least partially overlap the lower and upper surfaces in the third direction D3, opposite sidewalls in the first direction D1 and a sidewall in the second direction D2 of a corresponding one of the opposite edge portions in the second direction D2.

The body 810 may include a semiconductor material, e.g., silicon, germanium, silicon-germanium, etc., and n-type impurities and/or p-type impurities may be doped in a portion of the body 810. The electrode 820 may include a metal, e.g., copper, nickel, etc.

The second semiconductor chip 800 may serve as a passive element, e.g., diodes, condensers, etc.

The underfill member 734 may be disposed in the sixth opening 494, and may cover or at least partially overlap a lower surface of the fifth pad 732 in the third direction D3, a sidewall of the fifth pad 732 in the second direction D2, and an upper sidewall of the second semiconductor chip 800 in the second direction D2. In example embodiments, the underfill member 734 may be disposed only in an inside of the sixth opening 494, and may not be disposed outside of the sixth opening 494.

The underfill member 734 may include, e.g., an organic material, e.g., epoxy, polymer, etc.

As illustrated below with reference to FIGS. 2 to 13, the underfill member 734 may be disposed only in the inside of the sixth opening 494 without forming a structure serving as a dam at an area adjacent to the underfill member 734. Thus, the underfill member 734 may not contact the conductive connection member 720, and may not cover or overlap a surface of the conductive connection member 720. Accordingly, poor electrical connection between the conductive connection member 720 and other elements due to the underfill member 734 may be prevented.

As a result, the semiconductor package including the underfill member 734 and the conductive connection member 720 may have enhanced electric characteristics, and may have increased integration degree by saving the space for the structure serving as the dam.

The underfill member 734 may not be formed by a conventional underfill process, and the fifth pad 732 may be disposed between and contact the second semiconductor chip 800 and the first RDL 500, so that the underfill member 734 may also be referred to as a second protective layer.

FIGS. 2 to 13 are plan views and cross-sectional views illustrating a method of manufacturing a semiconductor package in accordance with example embodiments. Particularly, FIGS. 2, 8, 10 and 12 are the plan views, and FIGS. 3-7, 9, 11 and 13 are cross-sectional views taken along lines A-A′ of corresponding plan views, respectively. FIGS. 8, 10 and 12 are drawing of a region X of FIG. 2.

Referring to FIGS. 2 and 3, a panel P including a package substrate 110 may be provided.

In example embodiments, the package substrate 110 may include first and second surfaces 112 and 114 opposite to each other in the third direction D3.

The panel P may include a plurality of die regions and a scribe lane region surrounding the die regions, and the panel P may be cut along the scribe lane region by a sawing process to be singulated into each of the die regions.

In each of the die regions of the panel P, a wiring structure 120 extending through the package substrate 110 may be formed. In example embodiments, the wiring structure 120 may include, e.g., substrate pads, contact plugs, vias, wirings, etc., some of which are shown in FIG. 3.

For example, a laser process may be performed on the panel P to form a first opening 130 extending through the package substrate 110. In example embodiments, a plurality of first openings 130 may be spaced apart from each other in each of the first and second directions D1 and D2, and each of the first openings 130 may be formed in each of the die regions of the panel P.

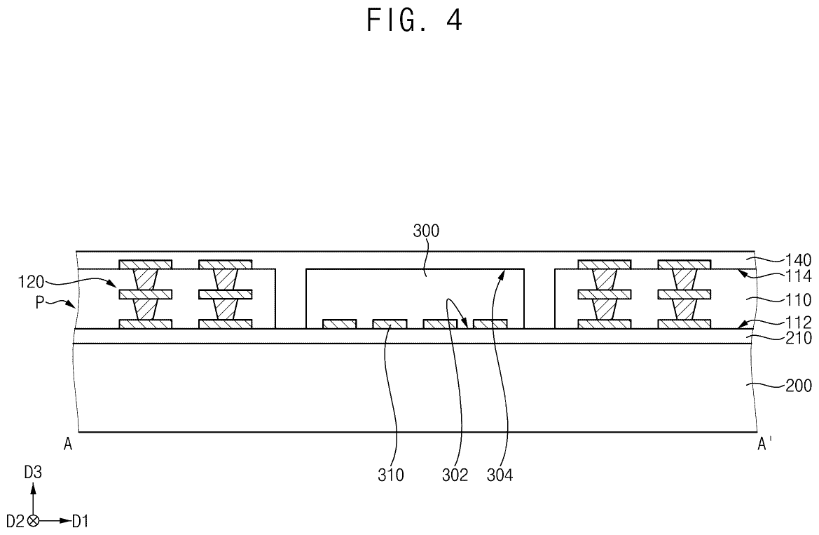

Referring to FIG. 4, the panel P may be mounted on a temporary adhesion layer 210 on a stage 200.

The temporary adhesion layer 210 may include a material that may lose adhesion by irradiating light or heating. In an example embodiment, the temporary adhesion layer 210 may include a release tape.

When the panel P is mounted on the stage 200, the first surface 112 of package substrate 110 may contact an upper surface of the temporary adhesion layer 210.

A first semiconductor chip 300 may be mounted into the first opening 130. The first semiconductor chip 300 may include first and second surfaces 302 and 304 opposite to each other in the third direction D3, and the first surface 302 of the first semiconductor chip 300 may contact an upper surface of a portion of the temporary adhesion layer 210 exposed by the first opening 130. In example embodiments, chip pads 310 that are disposed in the first semiconductor chip 300 may contact the upper surface of the portion of the temporary adhesion layer 210.

A molding layer 140 may be formed on the temporary adhesion layer 210, the first semiconductor chip 300 and the package substrate 110 to at least partially fill the first opening 130.

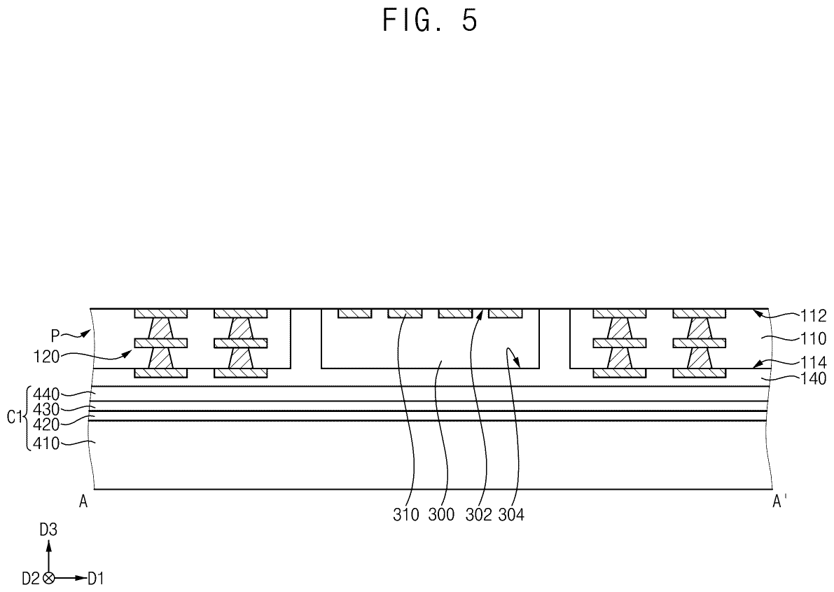

Referring to FIG. 5, a first carrier C1 may be bonded to an upper surface of the molding layer 140, the panel P may be separated from the temporary adhesion layer 210 on the stage 200, and a structure including the panel P, the first semiconductor chip 300, the molding layer 140 and the first carrier C1 may be flipped, so that the first surface 112 of the package substrate 110 and the first surface 302 of the first semiconductor chip 300 may face upwardly in the third direction D3.

In an example embodiment, the first carrier C1 may include a first carrier substrate 410, a first metal layer 420, a second metal layer 430 and a first adhesion layer 440, and the first adhesion layer 440 may contact the molding layer 140. The first carrier substrate 410 may include, e.g., a semiconductor material, an organic material, glass, etc., and each of the first and second metal layers 420 and 430 may include a metal, e.g., copper.

The first adhesion layer 440 may include, e.g., epoxy. In an example embodiment, the first adhesion layer 440 may include Ajinomoto build-up film (ABF).

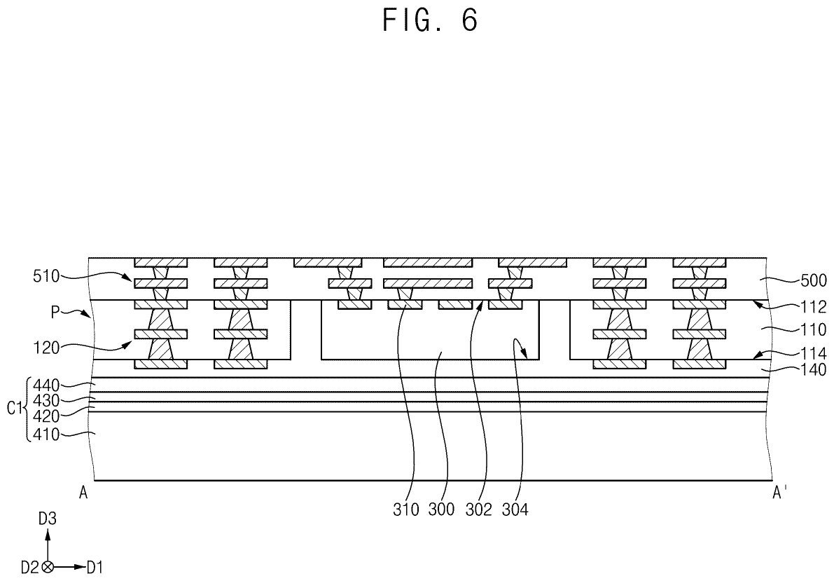

Referring to FIG. 6, a first redistribution layer (RDL) 500 may be formed on the package substrate 110, the first semiconductor chip 300 and the molding layer 140.

The first RDL 500 may contact the first surface 112 of the package substrate 110 and the first surface 302 of the first semiconductor chip 300.

The first RDL 500 may include first insulating interlayers stacked in the third direction D3 and a first redistribution wiring structure 510 in the first insulating interlayers. The first redistribution wiring structure 510 may include, e.g., first pads, contact plugs, vias and wirings, some of which are shown in FIG. 6.

In example embodiments, the first redistribution wiring structure 510 may contact the wiring structure 120 of the package substrate 110 and the chip pad 310 of the first semiconductor chip 300 to be electrically connected thereto.

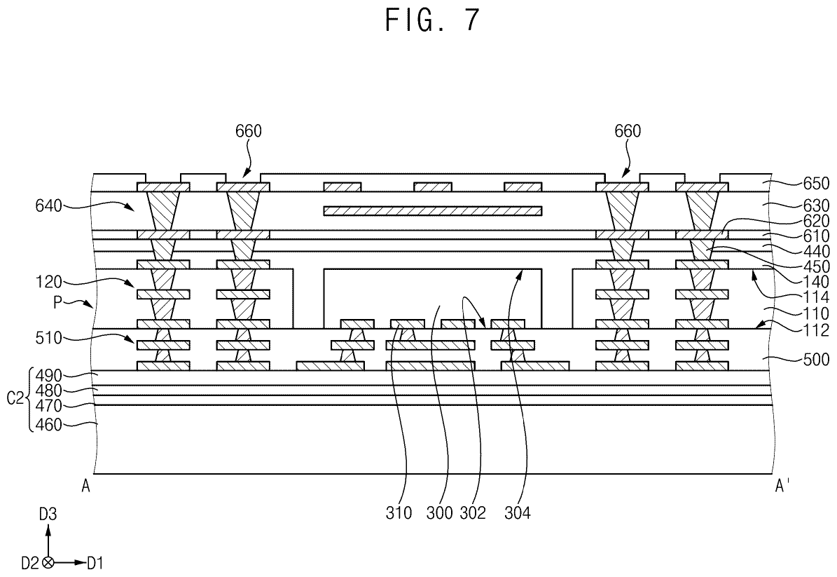

Referring to FIG. 7, a second carrier C2 may be bonded to an upper surface 504 of the first RDL 500, a structure including the panel P, the first semiconductor chip 300, the molding layer 140, the first RDL 500 and the first and second carriers C1 and C2 may be flipped, and the first carrier substrate 410 and the first metal layer 420 included in the first carrier C1 may be removed.

In an example embodiment, the first and second metal layers 420 and 430 may be separated from each other by a cutting process using a blade, and the first metal layer 420 and the first carrier substrate 410 bonded thereto may be removed.

In an example embodiment, the second carrier C2 may include a second carrier substrate 460, a third metal layer 470, a fourth metal layer 480 and a second adhesion layer 490 sequentially stacked in the third direction D3, and the second adhesion layer 490 may contact the first RDL 500. The second carrier substrate 460 may include, e.g., a semiconductor material, an organic material, glass, etc., and each of the third and fourth metal layers 470 and 480 may include a metal, e.g., copper.

The second adhesion layer 490 may include, e.g., epoxy. In an example embodiment, the second adhesion layer 490 may include ABF. The second adhesion layer 490 may also be referred to as a first insulation layer.

The second metal layer 430 may be removed to expose an upper surface of the first adhesion layer 440, a laser process may be performed to form a second opening extending through the first adhesion layer 440 and an upper portion of the molding layer 140 and exposing upper surfaces of some of the wiring structure 120, e.g., upper surfaces of the substrate pads, and a conductive via 450 may be formed in the second opening.

A second insulation layer 610 may be formed on the first adhesion layer 440 and the conductive via 450, a laser process may be performed to form a third opening extending through the second insulation layer 610 and exposing an upper surface of the conductive via 450, and a second pad 620 may be formed in the third opening.

A second RDL 630 may be formed on the second insulation layer 610 and the second pad 620.

The second RDL 630 may include second insulating interlayers stacked in the third direction D3 and a second redistribution wiring structure 640 in the second insulating interlayers. The second redistribution wiring structure 640 may include, e.g., third pads, contact plugs, vias, wirings, etc., some of which are shown in FIG. 7.

In example embodiments, the second redistribution wiring structure 640 may contact the second pad 620 to be electrically connected thereto.

A first protective layer 650 may be formed on the second RDL 630, and a fourth opening may be formed through an upper portion of the first protective layer 650 to expose some of the third pads.

Referring to FIGS. 8 and 9, a structure including the panel P, the first semiconductor chip 300, the molding layer 140, the first and second RDLs 500 and 630, the second carrier C2, etc., may be flipped, and the second carrier substrate 460 and the third metal layer 470 included in the second carrier C2 may be removed.

In an example embodiment, the third and fourth metal layers 470 and 480 may be separated from each other by a cutting process using a blade, and the third metal layer 470 and the second carrier substrate 460 bonded thereto may be removed.

The fourth metal layer 480 may be removed to expose an upper surface of the second adhesion layer 490, a laser process may be performed to form a fifth opening extending through the second adhesion layer 490 and exposing some of the first redistribution wiring structure 510, e.g., the first pad, and a fourth pad 710 may be formed in the fifth opening 492. In example embodiments, a plurality of fifth openings 492 may be spaced apart from each other in each of the first and second directions D1 and D2 at a portion of the second adhesion layer 490 corresponding to each of the die regions of the panel P, and thus a plurality of fourth pads 710 may be formed to be spaced apart from each other in each of the first and second directions D1 and D2.

In an example embodiment, each of the fourth pads 710 may at least partially fill the fifth opening 492, and may protrude or extend upwardly above the fifth opening 492. Additionally, a portion of each of the fourth pads 710 may also be formed on an upper surface of a portion of the second adhesion layer 490 adjacent to the fifth opening 492.

A portion of the second adhesion layer 490 may be removed by a laser process to form a sixth opening 494 exposing some of the first redistribution wiring structure 510, e.g., the first pad. In example embodiments, the sixth opening 494 may extend in the first direction D1, and a plurality of sixth openings 494, e.g., two sixth openings 494 may be formed to be spaced apart from each other in the second direction D2.

In example embodiments, each of the sixth openings 494 may overlap the first semiconductor chip 300 in the third direction D3.

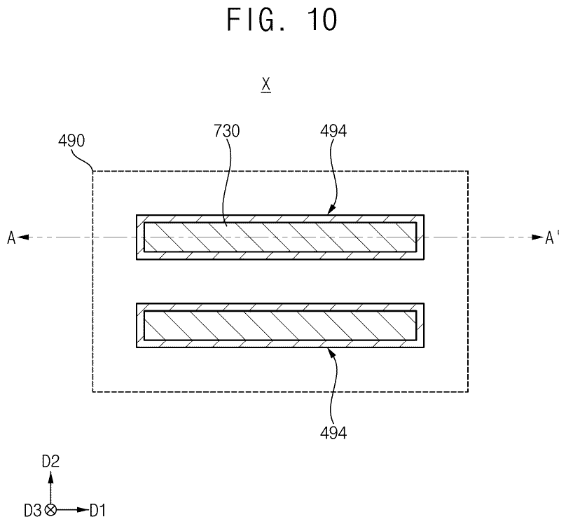

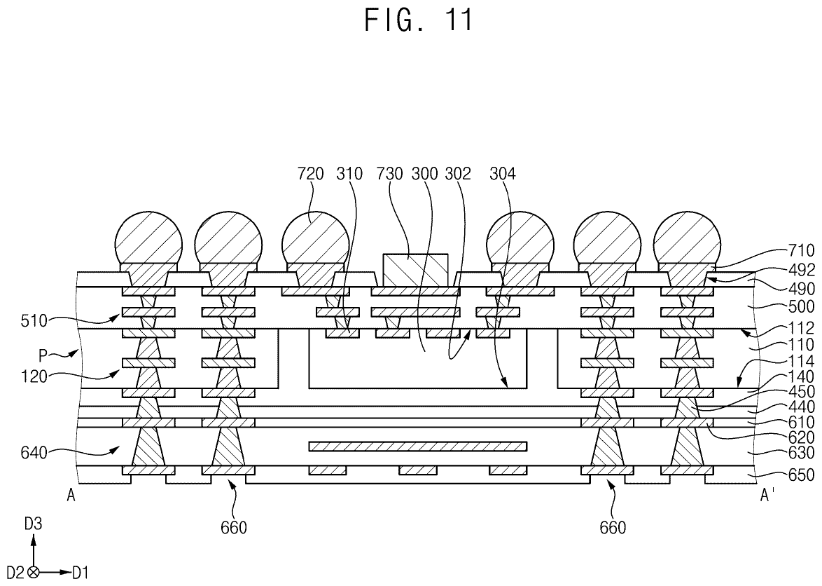

Referring to FIGS. 10 and 11, a complex adhesion layer 730 may be coated onto the first pad exposed by the sixth opening 494, flux may be coated onto the fourth pad 710, and a conductive connection member 720 may be mounted on the flux.

In example embodiments, the complex adhesion layer 730 may be a compound including a conductive material, e.g., solder and an organic material, e.g., epoxy. The complex adhesion layer 730 may extend in the first direction D1 in the sixth opening 494 extending in the first direction D1. In an example embodiment, a thickness of the complex adhesion layer 730 in the third direction D3 may be greater than a thickness of the second adhesion layer 490 in the third direction D3.

In example embodiments, the conductive connection member 720 may be a conductive bump or a conductive ball including solder.

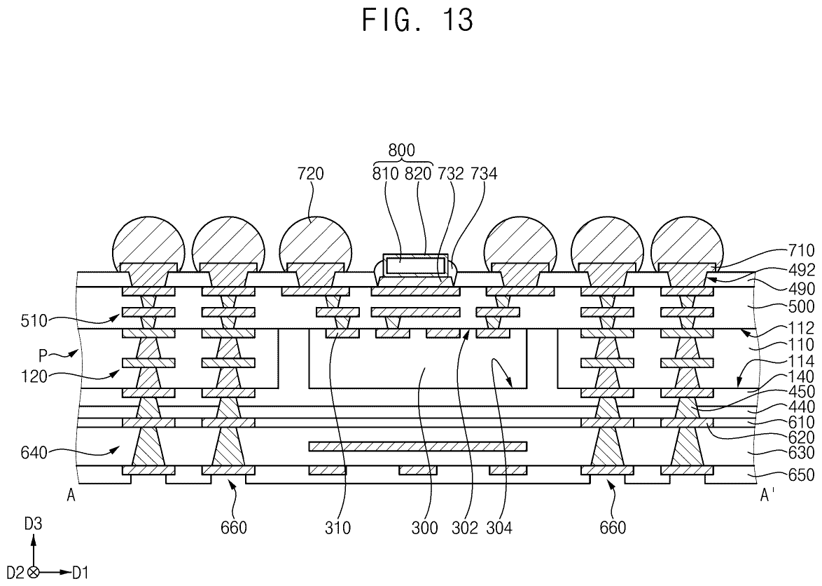

Referring to FIGS. 12 and 13, a second semiconductor chip 800 may be mounted on the complex adhesion layer 730, and a reflow process may be performed on the conductive connection member 720 including solder and the complex adhesion layer 730.

The second semiconductor chip 800 may include a body 810 and electrodes 820 covering or at least partially overlapping opposite edge portions of the body 810. Each of the electrodes 820 may extend in the first direction D1, and may cover or at least partially overlap the lower and upper surfaces of the body 810 in the third direction D3, opposite sidewalls of the body 810 in the first direction D1, and a sidewall in the second direction D2 of a corresponding one of the opposite edge portions in the second direction D2.

As the reflow process is performed, the complex adhesion layer 730 may be divided into a fifth pad 732 bonded to the upper surface of the first pad and an underfill member 734 covering or at least partially overlapping an upper surface and a sidewall of an edge portion of the fifth pad 732 in the third direction D3 and the first direction D1, respectively. The fifth pad 732 may include solder, and the underfill member 734 may include epoxy.

In example embodiments, the fifth pad 732 may be formed in the sixth opening 494. After the semiconductor package of FIG. 13 is flipped such that it corresponds to FIG. 1, the lower surface of the fifth pad 732 may be higher than or substantially coplanar with a bottom end of the sixth opening 494, that is, the lower surface of the second adhesion layer 490. For example, the lower surface of the fifth pad 732 and the lower surface 502 of the first RDL 500 are separated by a first distance in the third direction D3, the bottom of the sixth opening 494 and the lower surface 502 of the first RDL 500 are separated by a second distance in the third direction D3, and the first distance is less than or equal to the second distance.

In example embodiments, the underfill member 734 may be formed in an inside of the sixth opening 494 and may not be formed outside of the sixth opening 494 in a plan view. That is, as the reflow process is performed, the underfill member 734 divided from the complex adhesion layer 730 may have an upper surface lower than the complex adhesion layer 730 (e.g., a thickness of the underfill member 734 in the third direction D3 is less than a thickness of the complex adhesion layer 730) and a planar area greater than the complex adhesion layer 730, however, a sidewall of the second adhesion layer 490 at which the sixth opening 494 is formed may serve as a dam, so that the underfill member 734 may not flow outside of the sixth opening 494.

Thus, the underfill member 734 may not contact a neighboring one of the conductive connection members 720 and may not cover or overlap a surface thereof. Accordingly, poor electrical connection between the conductive connection member 720 and other elements may be prevented.

By the reflow process, the conductive connection member 720 may cover or overlap an upper surface and a sidewall of the fourth pad 710 protruding or extending upwardly above the fifth opening 492.

Referring to FIG. 1 again, the panel P may be cut along the scribe lane region by, e.g., a sawing process to be singulated into a plurality of package substrates 110, which may be flipped.

During the sawing process, structures on and beneath the panel P may also be cut, which may form a unit semiconductor package together with the panel P.

As illustrated above, a portion of the second adhesion layer 490 may be removed to form the sixth opening 494 extending in the first direction D1 and exposing the first pad of the first redistribution wiring structure 510, the complex adhesion layer 730 including solder and epoxy may be formed on the first pad, the second semiconductor chip 800 including the electrode 820 may be mounted on the complex adhesion layer 730, the reflow process may be performed on the complex adhesion layer 730, so that the fifth pad 732 contacting and electrically connecting the electrode 820 and the first pad with each other, and the underfill member 734 covering or overlapping the edge portion of the fifth pad 732 and a lower portion of the second semiconductor chip 800 may be formed.

If, for example, a plurality of sixth openings 494 is formed to be spaced apart from each other in the first direction D1, a conductive layer is formed on the second adhesion layer 490 to extend in the first direction D1 and fill the sixth opening 494, solder paste is printed onto the conductive layer, the second semiconductor chip 800 including the electrode 820 is mounted on the solder paste, a reflow process is performed on the solder paste to form the fifth pad 732, and an underfill process is performed to form the underfill member 734 covering or overlapping the edge portion of the fifth pad 732 and the lower portion of the second semiconductor chip 800, the underfill member 734 may partially contact and cover/overlap a surface of a neighboring one of the conductive connection members 720, so that the electrical connection between the conductive connection member 720 and other elements may be poor.

In order to prevent the poor electrical connection, an additional structure serving as a dam has to be formed on the second adhesion layer 490 so that the processes may be complicated and that the integration degree of the semiconductor package may be reduced due to an additional space for forming the dam.

However, in example embodiments, the underfill member 734 may be formed by a reflow process on the complex adhesion layer 730 in the sixth opening 494, and during the reflow process, the sidewall of the second adhesion layer 490 where the sixth opening 494 is formed may serve as a dam, so that the underfill member 734 may not contact a neighboring one of the conductive connection members 720. Thus, the process for manufacturing the semiconductor package may be simplified, and the integration degree of the semiconductor package may be enhanced.

The underfill member 734 may be formed by other processes that are different from the conventional processes, and thus may also be referred to as a second protective layer instead of the underfill member 734.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

1. A semiconductor package comprising:
a first redistribution layer (RDL) comprising a first redistribution wiring structure;
a package substrate on an upper surface of the first RDL;
a first semiconductor chip on the first RDL, the first semiconductor chip spaced apart from the package substrate in a first direction that is parallel to the upper surface of the first RDL;
an insulation layer contacting a lower surface of the first RDL, the insulation layer comprising an opening exposing a lower surface of a portion of the first redistribution wiring structure;
a pad in the opening, the pad contacting the lower surface of the portion of the first redistribution wiring structure and comprising solder;
a second semiconductor chip contacting a lower surface of the pad, the second semiconductor chip comprising a passive element; and
an underfill member in the opening, the underfill member not contacting a portion of a lower surface of the insulation layer adjacent to the opening, and the underfill member at least partially overlapping sidewalls of the pad and the second semiconductor chip in the first direction.

2. The semiconductor package according to claim 1, wherein the lower surface of the pad and the lower surface of the first RDL are separated by a first distance in a second direction that is perpendicular to the upper surface of the first RDL, the lower surface of the insulation layer and the lower surface of the first RDL are separated by a second distance in the second direction, and wherein the first distance is less than the second distance.

3. The semiconductor package according to claim 1, wherein an upper surface of the pad is substantially coplanar with the lower surface of the first RDL.

4. The semiconductor package according to claim 1, wherein the pad extends in the first direction.

5. The semiconductor package according to claim 4, wherein the opening has a width in the first direction that gradually decreases from a bottom of the opening to a top of the opening that exposes the lower surface of the portion of the first redistribution wiring structure.

6. The semiconductor package according to claim 1, wherein a lower surface of the underfill member does not contact a lower surface of the second semiconductor chip.

7. The semiconductor package according to claim 1, wherein a lower surface of the underfill member and the lower surface of the first RDL are separated by a first distance in a second direction that is perpendicular to the upper surface of the first RDL, a lower surface of the second semiconductor chip and the lower surface of the first RDL are separated by a second distance in the second direction, and the first distance is less than the second distance.

8. The semiconductor package according to claim 1, further comprising a molding layer on the first RDL and between the package substrate and the first semiconductor chip, the molding layer at least partially overlapping upper surfaces of the package substrate and the first semiconductor chip in a second direction that is perpendicular to the upper surface of the first RDL.

9. The semiconductor package according to claim 8, further comprising a second RDL on the molding layer, the second RDL comprising a second redistribution wiring structure.

10. A semiconductor package comprising:
a redistribution layer (RDL) comprising a redistribution wiring structure;
a package substrate on an upper surface of the RDL;
a first semiconductor chip on the RDL, the first semiconductor chip spaced apart from the package substrate in a first direction that is parallel to the upper surface of the RDL;
an insulation layer contacting a lower surface of the RDL, the insulation layer comprising an opening exposing a lower surface of a portion of the redistribution wiring structure;
a pad in the opening, the pad contacting the lower surface of the portion of the redistribution wiring structure and comprising solder, and an upper surface of the pad is substantially coplanar with the lower surface of the RDL;
a second semiconductor chip contacting a lower surface of the pad, the second semiconductor chip comprising a passive element; and
a protective layer at least partially at least partially overlapping sidewalls of the pad and the second semiconductor chip in a second direction that is perpendicular to the upper surface of the RDL, the protective layer comprising epoxy.

11. The semiconductor package according to claim 10, wherein the lower surface of the pad and the lower surface of the RDL are separated by a first distance in the second direction, a lower surface of the insulation layer and the lower surface of the RDL are separated by a second distance in the second direction, and wherein the first distance is less than the second distance.

12. The semiconductor package according to claim 10, wherein the opening has a width in the first direction that gradually decreasing decreases from a bottom of the opening to a top of the opening that exposes the lower surface of the portion of the first redistribution wiring structure.

13. The semiconductor package according to claim 10, wherein the protective layer does not contact a portion of a lower surface of the insulation layer adjacent to the opening.

14. The semiconductor package according to claim 10, wherein a lower surface of the protective layer does not contact a lower surface of the second semiconductor chip.

15. The semiconductor package according to claim 10, wherein a lower surface of the protective layer and the lower surface of the RDL are separated by a first distance in the second direction, a lower surface of the second semiconductor chip and the lower surface of the RDL are separated by a second distance in the second direction, and the first distance is less than the second distance.

16. A semiconductor package comprising:
a redistribution layer (RDL) comprising a redistribution wiring structure;
a package substrate on an upper surface of the RDL;
a first semiconductor chip on the RDL, the first semiconductor chip spaced apart from the package substrate in a first direction that is parallel to the upper surface of the RDL;
an insulation layer contacting a lower surface of the RDL, the insulation layer comprising a first opening and a second opening that expose a first portion of the redistribution wiring structure and a second portion of the redistribution wiring structure, respectively;
a first pad in the first opening and contacting the first portion of the redistribution wiring structure;
a second pad in the second opening and contacting the second portion of the redistribution wiring structure;
a conductive connection member contacting a lower surface of the first pad;
a second semiconductor chip contacting a lower surface of the second pad; and
an underfill member in the second opening, wherein:
the lower surface of the second pad and the lower surface of the RDL are separated by a first distance in a second direction that is perpendicular to the upper surface of the RDL,
a lower surface of the insulation layer and the lower surface of the RDL are separated by a second distance in the second direction, and
the underfill member does not contact a portion of a lower surface of the insulation layer between the first opening and the second opening.

17. The semiconductor package according to claim 16, wherein the underfill member at least partially overlaps sidewalls of the second pad and the second semiconductor chip in the first direction.

18. The semiconductor package according to claim 16, wherein the first distance is less than or equal to the second distance.

19. The semiconductor package according to claim 16, wherein an upper surface of the second pad is substantially coplanar with the lower surface of the RDL.

20. The semiconductor package according to claim 16, wherein:
the first pad comprises a metal;
the second pad comprises solder;
the second semiconductor chip comprises a passive element;
the conductive connection member is a bump comprising solder; and
the insulation layer and the underfill member comprise an organic material.

21-25. (canceled)
